(19) United States
(12) Patent Application Publication
(10) Pub. No.: US 2026/0231784 A1
(43) Pub. Date: Aug. 6, 2026

(54) SEMICONDUCTOR PACKAGE WITH TOP-SIDE BASE PLATE

(71) Applicant: Semihow. Co., Ltd., Bucheon-si (KR)

(72) Inventors: Myounghwan KIM, Incheon (KR); Inhyuk SONG, Suwon-si (KR); Kyoungwon BAEK, Bucheon-si (KR)

(73) Assignee: Semihow. Co., Ltd., Bucheon-si, Gyeonggi-do, (KR)

(21) Appl. No.: 19/357,903

(22) Filed: Oct. 14, 2025

(30) Foreign Application Priority Data
Feb. 4, 2025 (KR) 10-2025-0013633

(51) Int. Cl. H10W 70/40; H10W 74/10

(52) U.S. Cl. CPC H10W 70/429; H10W 70/461; H10W 74/114

(57) ABSTRACT

A semiconductor package includes a housing, forming an outer shape sealed with an encapsulant; a base plate, fixed to a top surface of the housing so as to be exposed, and including a first lead portion and a second lead portion to be electrically connected to a printed circuit board; and a plurality of pins, extending in a first lateral direction of the housing so as to be exposed, and electrically connected to the printed circuit board.

### CROSS-REFERENCE TO RELATED APPLICATION

The present application claims priority under 35 U.S.C. § 119(a) to Korean application number 10-2025-0013633, filed on February 4, 2025, in the Korean Intellectual Property Office, which is incorporated herein by reference in its entirety.

### BACKGROUND

The present disclosure relates to a semiconductor package with a base plate provided on a top surface thereof.

A semiconductor package has the appearance of a housing sealed with an EMC (Epoxy Mold Compound) and having one or more semiconductor components. Typically, a base plate is disposed on the bottom surface of the housing facing a printed circuit board (PCB), and a semiconductor component is mounted on the top surface of the base plate and disposed inside the housing.

A semiconductor package provided with the semiconductor component and the base plate is mounted on the PCB to facilitate electrical connection and heat transfer. The semiconductor package is electrically connected to the PCB by using a plurality of pins wire-bonded to be electrically connected to the semiconductor component.

The semiconductor component generates significant amount of heat during operation. However, the heat dissipation efficiency of the semiconductor package is ineffective, even when the base plate is arranged close to the PCB on the bottom surface of the housing.

To solve this problem, U.S. Patent No. 10,658,276 discloses a semiconductor package with a top-side cooling structure in which a base plate is disposed on a top surface of a housing that is far from the PCB.

Referring to FIG. 1, a semiconductor package 10 includes a housing 11 that forms an outer shape and is sealed with the EMC, a base plate 13 that is disposed on the top surface of the housing 11 and is exposed upward, and a plurality of pins 15 that extend outward through one side of the housing 11. Each of the pins 15 is electrically connected to semiconductor components mounted on the bottom surface (i.e., a surface opposite to the upwardly exposed surface) of the base plate 13 inside the housing 11.

The base plate 13 is fixed to the housing 11 and extends in a horizontal direction from the top surface of the housing 11 to the outside of the housing 11. As a result, in the semiconductor package 10, the base plate 13 is shaped to be continuous in the lateral direction and entirely exposed upward. The base plate 13 is made of a metal, such as copper.

For the sake of clarity, the different areas of the base plate 13 will be identified by location. Specifically, the area of the base plate 13 disposed on the top surface of the housing 11 will be referred to as a base area, and the area of the base plate 13 extending in the horizontal direction and located outside the housing 11 will be referred to as an extended area.

The extended area is formed in the shape of T with branch areas extending in both directions from an outer end, and the branch areas are bent downward (i.e., toward the location of the electrically connected PCB) to form a lead 17. That is, in order for the base plate 13 to be disposed on the top surface of the housing 11, which is farthest from the PCB, the pins 15 provided in the semiconductor package 10 and the branch areas of the base plate 13 are each bent downward toward the PCB.

To effectively dissipate the heat generated during operation of the semiconductor component, a heat sink is arranged to be in contact with the base plate 13 disposed on the top surface of the housing 11.

However, the semiconductor package 10 illustrated in FIG. 1 is not only limited to use for low voltage applications of 650 V or less for the following reasons, but also has a problem of causing product defects during the manufacturing process of the semiconductor package 10.

First, in the EMD molded housing 11, a recessed pressing pin groove 40 is formed in the area where a pressing pin (not shown) pressing the base plate 13 is located. In the semiconductor package 10 manufacturing process, the EMC molding work is performed after the wire bonding work for the semiconductor component is completed. In order to prevent EMC penetration into the opposite surface of the base plate 13 or distortion of the pins’ position, the EMC molding work is performed while the base plate 13 is pressed by a pressing pin, and once the EMC molding work is complete, the pressing pin is removed.

Since the area where the pressing pin was located is not filled with the EMC during the EMC molding process, the area where the pressing pin was located is formed as the pressing pin groove 40, and a portion of the bottom surface of the base plate 13 (i.e., the area where the base plate 13 was pressed by the pressing pin) is exposed to the outside through the pressing pin groove 40.

However, as shown in FIG. 1, the formation position of the pressing pin groove 40 is very close to the pins 15. This results in an insufficient creepage distance between the pins 15 and the base plate 13 exposed through the top surface of the semiconductor package 10 or the pressing pin groove 40, which is required in the high-voltage semiconductor package 10.

Second, the base plate 13 has the extended area located outside the housing 11, and the branch areas of the extended area are bent downward to form a lead 17. Generally, the base plate 13 is formed integrally to electrically connect the base area and the extended area.

However, during the forming process for forming the lead 17 after the EMC molding is complete, force generated during the process of bending the branch areas is transferred to the base plate 13, causing product defects such as bending of the base area of the base plate 13 or poor adhesion between the housing 11 and the base area. As indicated by A in FIG. 1, there is no structure for dispersing force between the base area and the extended area of the base plate 13. Consequently, the force generated in the extended area during the bending process of the branch areas is transferred to the base area of the base plate 13.

When the base area of the base plate 13 is bent or when the force causing bending is transferred to the base area, the adhesion between the EMC housing 11 and the base area decreases, causing a gap between the edge of the base area and the housing 11, allowing moisture to penetrate into the gap between the edge of the base area and the housing 11, and consequently lowering the operational reliability of the semiconductor package 10.

The foregoing background art consists of technical information that the inventor used to develop the present disclosure or acquired during the development process. It is not necessarily technology that was publicly disclosed before the present disclosure was filed.

### SUMMARY

The present disclosure is to provide a semiconductor package with a top-side base plate, which can prevent a base area of the base plate from bending, even when a portion of an extended area of the base plate is bent to form a lead portion, thereby ensuring the operational reliability of a semiconductor package.

The present disclosure is to provide a semiconductor package with a top-side base plate, in which a creepage distance between pins, which are electrically connected to a printed circuit board, and a base plate can be secured to satisfy a reference value required for a high-withstand voltage semiconductor package.

Other technical problems to be solved by the present disclosure will be easily understood through the following description.

According to one aspect of the present disclosure, there is provided a semiconductor package, including: a housing, forming an outer shape sealed with an encapsulant; a base plate, fixed to a top surface of the housing so as to be exposed, and including a first lead portion and a second lead portion electrically connected to a printed circuit board; and a plurality of pins, extending in a first lateral direction of the housing so as to be exposed, and electrically connected to the printed circuit board, wherein a bottom surface of the housing faces the printed circuit board such that the semiconductor package is electrically connected to the printed circuit board, wherein the base plate includes a base area located on the top surface of the housing, and an extended area located outside the housing by extending from the base area in a second lateral direction opposite to the first lateral direction, and including the first lead portion and the second lead portion, wherein the base area is exposed upward from the housing and the base plate is fixed to the housing such that an edge area of the base area is continuously covered with the encapsulant, wherein, in a top view, the base area and the extended area are separated from each other by a contact zone, which is a partial area of the housing existing between the base area and the extended area to distinguish the base area and the extended area.

The extended area includes a flat extended portion connected to the base area and extending outward from the housing, and the first lead portion and the second lead portion, each connected to the base area and extending outward from the housing at a height corresponding to the bottom surface of the housing, and bent, wherein the first lead portion and the second lead portion are respectively located to be spaced apart from each other on both sides of the flat extended portion, with the flat extended portion interposed therebetween, and wherein, in the first lead portion, the flat extended portion, and the second lead portion disposed side by side in a width direction, each of the first lead portion and the second lead portion is formed to have a relatively small width compared to the flat extended portion.

In an initial configuration where the base plate is fixed to the housing such that the base area is exposed upward and the edge area of the base area is continuously surrounded by the housing, T-shaped protrusions connected to the base area are formed at each of both ends of the extended area, and a central area is formed in a shape protruding from the base area so as to be spaced apart between the T-shaped protrusions, and a π-shaped protrusion is formed outward from the central area, and the outer ends of the T-shaped protrusions and the outer end of the π-shaped protrusion are connected to each other, the T-shaped protrusions and the central area are separated from each other by cutting the π-shaped protrusion in a trimming process, wherein the central area is maintained as the flat extended portion, and each of the T-shaped protrusions is formed into the first lead portion and the second lead portion by a forming process.

The base area is an area in contact with a heat sink for heat dissipation, and the flat extended portion, which is located lower than a top surface height of the base area, is an area for dissipating heat into the air. Alternatively, the base area and the flat extended portion separated by the contact zone have same top surface height, so that the base area and the flat extended portion are in contact with a heat sink for heat dissipation together.

One or more semiconductor components are mounted on a surface opposite to the base area in contact with the heat sink, and the semiconductor components are sealed with the encapsulant and located inside the housing.

In order for a distance of a first shortest path between the base area and the pin exposed in the top surface of the housing to be 6.3 mm or more, a first distance extension groove is formed in the top surface of the housing between the base area and the pin in a shape orthogonal to the first shortest path.

A pressing pin groove for exposing a bottom surface of the base area is formed on a side surface of the housing, and the pressing pin groove is formed at a position closer to the extended area than the pin.

In order for a distance of a second shortest path between the base area exposed through the pressing pin groove and the pin to be 6.3 mm or more, a second distance extension groove is formed in the bottom surface of the housing between the pressing pin groove and the pin in a shape intersecting the second shortest path.

Other aspects, features, and advantages than those described above will become apparent from the drawings, the claims, and the detailed description of the disclosure below.

According to one embodiment of the present disclosure, it is advantageous to provide a semiconductor package with a top-side base plate, which can prevent a base area of the base plate from bending, even when a portion of an extended area of the base plate is bent to form a lead portion, thereby ensuring the operational reliability of a semiconductor package.

It is also advantageous to provide a semiconductor package with a top-side base plate, in which a creepage distance between pins, which are electrically connected to a printed circuit board, and a base plate can be secured to satisfy a reference value required for a high-withstand voltage semiconductor package.

The effects obtainable from the present disclosure are not limited to the effects mentioned above, and other effects not mentioned will be clearly understood by those skilled in the art from the description below.

### BRIEF DESCRIPTION OF ACCOMPANYING DRAWINGS

FIG. 1 shows an appearance of a semiconductor package according to the prior art;

FIG. 2 exemplarily illustrates an exterior shape of a semiconductor package according to one embodiment of the present disclosure;

FIG. 3 exemplarily illustrates an electrical connection structure of a base plate, a semiconductor component, and a pin according to one embodiment of the present disclosure;

FIG. 4, FIG. 5 and FIG. 6 exemplarily illustrate a process of forming a flat extended portion, a first lead portion, and a second lead portion according to one embodiment of the present disclosure;

FIG. 7 and FIG. 8 exemplarily illustrate explaining the formation of a creepage distance of a semiconductor package according to one embodiment of the present disclosure; and

FIG. 9 exemplarily illustrates an exterior shape of a semiconductor package according to another embodiment of the present disclosure.

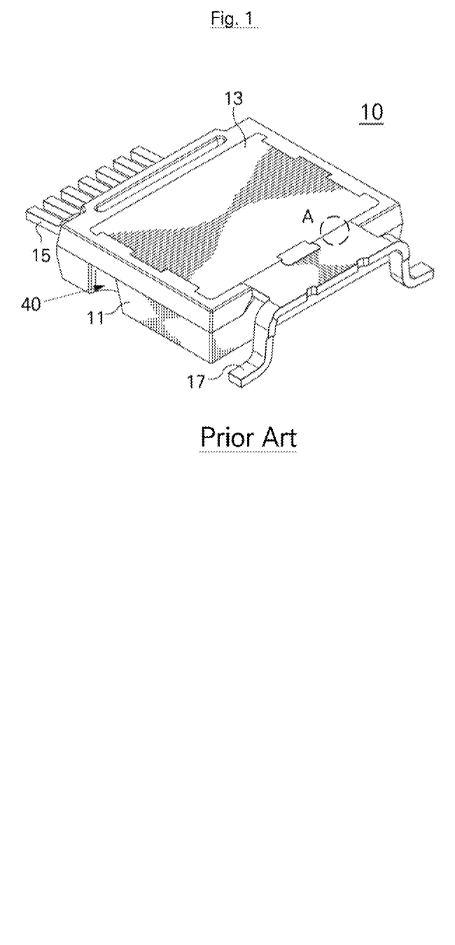

### DETAILED DESCRIPTION

The present disclosure can be subject to various modifications and have various embodiments, and specific embodiments will be illustrated in the drawings and described in detail in the detailed description. However, this is not intended to limit the present disclosure to a specific embodiment, and it should be understood to include all modifications, equivalents, or replacements included in the spirit and technical scope of the present disclosure. In the description of the present disclosure, when a detailed description of a related known technology is deemed to obscure the gist of the present disclosure, the detailed description thereof will be omitted.

Terms such as “first”, “second”, etc., may be used to refer to various elements, but, these elements should not be limited due to these terms. These terms will be used to distinguish one element from another element.

The terms used in the following description are intended to merely describe specific embodiments, but not intended to limit the disclosure. An expression of the singular number includes an expression of the plural number, so long as it is clearly read differently. The terms such as “comprise”, “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout the specification.

Terms such as "top", "bottom", "up", and "down" do not represent an absolute direction of an element or a part and are used for descriptive purposes only. In addition, relative terms, such as “below” or “above” or “upper” or “lower” or “horizontal” or “lateral” or “vertical” may be used herein to describe-one element, layer or region's relationship to another elements, layers or regions as illustrated in the drawings. It will be understood that relative terms are intended to encompass different orientations of the device in addition to the orientation depicted in the drawings.

Hereinafter, one embodiment of the present disclosure will be described in detail with reference to the accompanying drawings.

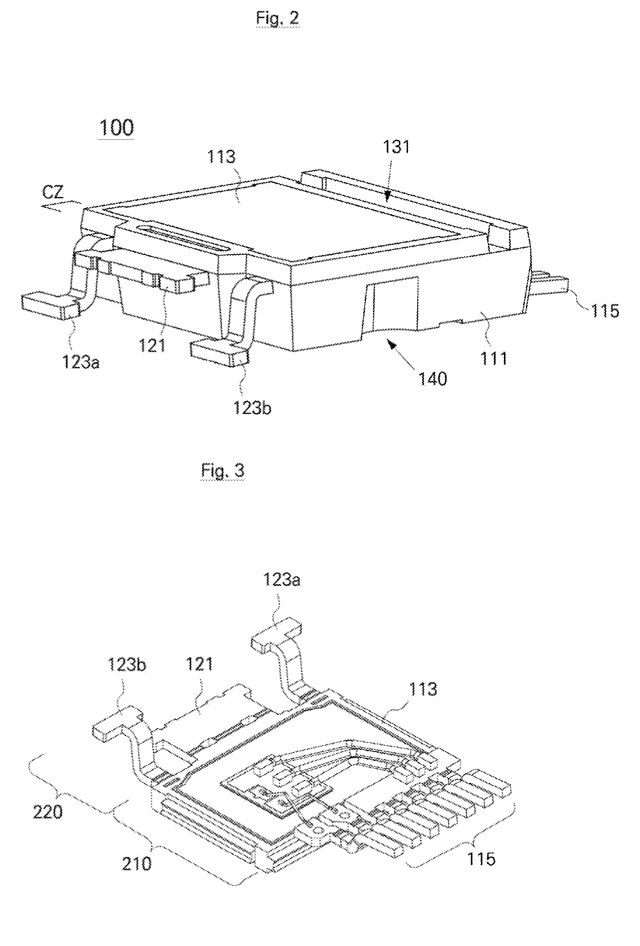

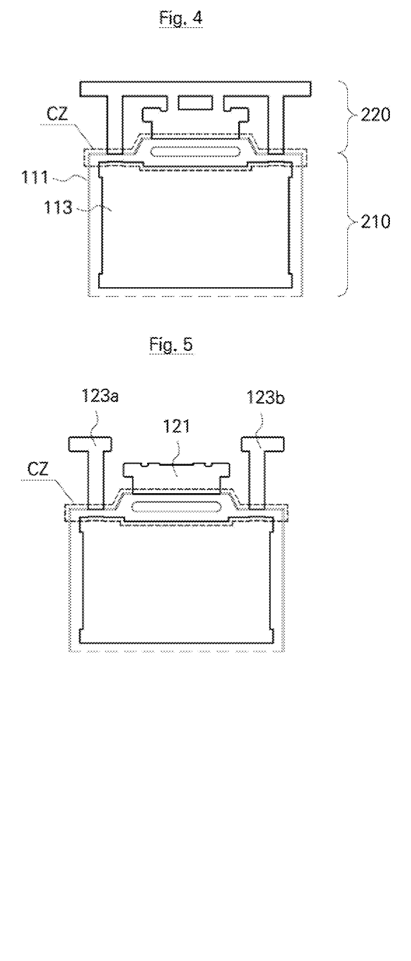

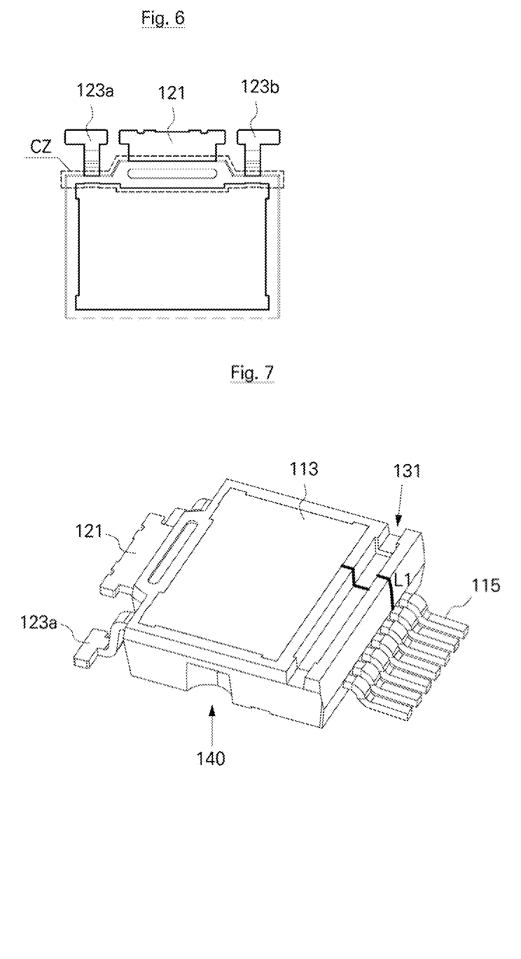

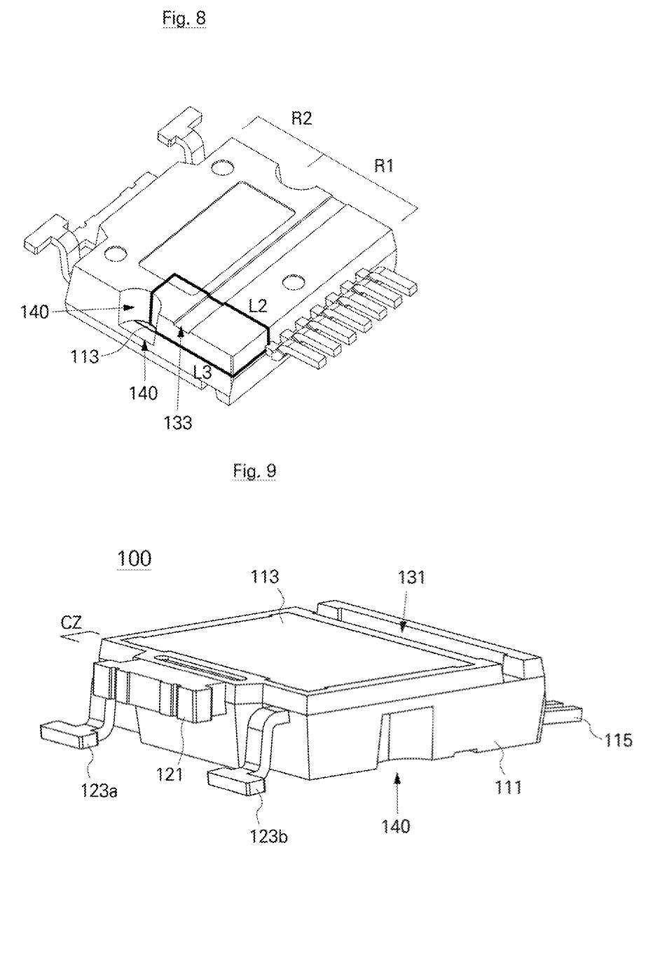

FIG. 2 exemplarily illustrates an exterior shape of a semiconductor package according to one embodiment of the present disclosure, and FIG. 3 exemplarily illustrates an electrical connection structure of a base plate, a semiconductor component, and a pin according to one embodiment of the present disclosure. FIGS. 4 to 6 exemplarily illustrate a process of forming a flat extended portion, a first lead portion, and a second lead portion according to one embodiment of the present disclosure, and FIGS. 7 and 8 exemplarily illustrate explaining the formation of a creepage distance of a semiconductor package according to one embodiment of the present disclosure.

Referring to FIG. 2, a semiconductor package 100 includes a housing 111 that forms an exterior shape sealed with an encapsulant, a base plate 113 that is disposed on the top surface of the housing 111 to be exposed upward, and a plurality of pins 115 that extend outward through one side of the housing 111. The encapsulant may be an insulating resin such as EMC (Epoxy Mold Compound).

Each of the pins 115 is electrically connected to a corresponding semiconductor component mounted on the base plate 113 through wire bonding (refer to FIG. 3). The semiconductor component may include one or more of a semiconductor element, a semiconductor chip, and an IC (integrated circuit) die, and may be mounted on a bottom surface (i.e., a surface opposite to the upwardly exposed surface) of the base plate 113. The semiconductor element provided in the semiconductor package 100 may be one or more of, for example, a MOSFET (Metal-Oxide-Semiconductor Field-Effect Transistor) element, an IGBT (Insulated Gate Bipolar Transistor) element, and the like.

After wire bonding for the semiconductor component and each of the pins 115 is completed, the housing 111 is formed using an encapsulant and the semiconductor component and other components are sealed. During the molding work, in order to prevent the encapsulant from penetrating into the opposite surface of the base plate 113 or the position of the pins 115 from being distorted, the EMC molding work is performed while the base plate 113 is pressed by a pressing pin, and once the EMC molding work is complete, the pressing pin is removed. The area where the pressing pin was located to press the base plate 113 forms a recessed pressing pin groove 140 in the housing 111.

When the semiconductor package 100 is mounted on a PCB, the bottom surface of the housing 111 is disposed close to the PCB, so the base plate 113 disposed on the top surface of the housing 111 is located farthest from the PCB.

The base plate 113 is fixed to the housing 111 to extend in a lateral direction from the top surface of the housing 111 to the outside of the housing 111. The base plate 113 may be formed of a metal such as copper.

For the sake of clarity, the different areas of the base plate 113 will be identified by location. Specifically, an area of the base plate 113 disposed on the top surface of the housing 111 will be referred to as a base area 210, and an area of the base plate 113 extending from the base area 210 in the lateral direction and located outside the housing 111 will be referred to as an extended area 220.

As shown in FIGS. 2 and 4 to 6, the base area 210 of the base plate 113 is exposed upwardly from the housing 111, while an edge area of the base area 210 is fixed to the upper surface of the housing 111 in a configuration where it is continuously covered by the encapsulation material for a predetermined width. As a result, in a top view, the base area 210 and the extended area 220 are separated from each other by the housing 111 formed to surround the edge area of the base area 210. A partial area of the housing 111 located above the boundary between the extended area 220 and the base area 210, which separates the extended area 220 and the base area 210, may be referred to as a contact zone (CZ).

In one example, the base plate 113 may be formed integrally, allowing the base area 210 and the extended area 220 to be formed as a single body. In another example, the base area 210 and the extended area 220 having separate bodies may be fixedly coupled together to form the base plate 113. In this example, in order for the shape of the base plate 113 to be stably maintained, the contact zone may be formed to completely cover the periphery of an area where the base area 210 and the extended area 220 are in contact.

The extended area 220, which extends outward from the base area 210 of the base plate 113 and is exposed outside the housing 111, includes a flat extended portion 121, a first lead portion 123a, and a second lead portion 123b.

The flat extended portion 121, the first lead portion 123a, and the second lead portion 123b are each formed to be spaced apart from each other in a lateral direction. The flat extended portion 121 is located in the middle, and the first lead portion 123a and the second lead portion 123b are each located on both sides of the flat extended portion 121. The first lead portion 123a and the second lead portion 123b each extend downward from the semiconductor package 100 (i.e., toward the PCB) and are bent to be parallel to the PCB.

A process of forming the flat extended portion 121, the first lead portion 123a, and the second lead portion 123b will be briefly described with reference to FIGS. 4 to 6.

As described above, the base plate 113 fixed in the top surface of the housing 111 has the base area 210 located on the top surface of the housing 111, and the extended area 220 extends in the lateral direction from the base area 210 and is located outside the housing 111.

FIG. 4 shows an initial configuration in which the base plate 113 is fixed to the housing 111 such that the base area 210 is exposed upward, and the edge area of the base area 210 is continuously surrounded by the housing 111.

In the initial configuration of the extended area 220, T-shaped protrusions connected to the base area 210 are formed at each of both ends of the extended area 220, and a central area is formed in a shape protruding from the base area 210 so as to be spaced apart between the T-shaped protrusions. Additionally, a π-shaped protrusion is formed outward from the central area, and the outer ends of the T-shaped protrusions and the outer end of the π-shaped protrusion are connected to each other.

A top surface height of the extended area 220 is formed to be relatively lower than that of the top surface of the base area 210, so the base plate 113 may be formed in an L shape when viewed from the side, and the extended area 220 may extend and be exposed outward through the side surface of the housing 111.

Thereafter, as shown in FIG. 5, a trimming process is performed to cut the π-shaped protrusion connected to each other, so that the T-shaped protrusions and the central area are separated from each other. The central area separated by the trimming process is maintained as a flat extended portion 121.

Thereafter, as shown in FIG. 6, a forming process is performed to form each of the T-shaped protrusions, which are spaced apart on both sides of the flat extended portion 121, into a first lead portion 123a and a second lead portion 123b, which extend downward from the housing 111 and are bent to be parallel to the PCB. In the forming process for forming the first lead portion 123a and the second lead portion 123b, the bending process for the pins 115 may be performed together.

The T-shaped protrusions for forming the first lead portion 123a and the second lead portion 123b may be formed with a relatively small width compared to the flat extended portion 121.

Accordingly, a relatively small force is generated in the bending process for each of the T-shaped protrusions having the relatively small width, and the generated small force is dispersed by the contact zone (CZ) in the process of being transferred to the base area 210 connected to the T-shaped protrusion with the small width, thereby preventing a bending phenomenon of the base area 210. By preventing the bending phenomenon of the base plate 113, a firm coupling between the housing 111 and the base plate 113 can be maintained, and moisture penetration into the inside of the semiconductor package can also be effectively suppressed.

In order for heat generated during operation of the semiconductor component to be effectively dissipated through a heat sink, a heat sink (not shown) may be disposed to be in contact with the base area 210 of the base plate 113 disposed on the top surface of the semiconductor package 100. The flat extended portion 121, which is located lower than a top surface height of the base area 210, can dissipate heat into the air while being spaced apart from the heat sink in a vertical direction.

In addition, the housing 111 of the semiconductor package 100 may be shaped to secure a creepage distance required for a high-voltage semiconductor package of, for example, 1250V or more. The creepage distance in the semiconductor package 100 means the shortest distance measured along the surface of an insulator between two conductors, and if the creepage distance is shorter than a required reference value, product failure may be caused by insulation breakdown due to a creeping phenomenon.

The creepage distance of the semiconductor package 100 may be measured as the shortest distance along the surface of the housing 111 between the pins 115 and the base plate 113, which are formed of a metal material. That is, the creepage distance may be measured as the shortest distance among a path L1 (refer to FIG. 7) passing from the pins 115 along the side and top surfaces of the housing 111, a path L2 (refer to FIG. 8) passing along the side surfaces of the housing 111 to the bottom surface of the base plate 113 exposed through the pressing pin groove 140, and a path L3 (refer to FIG. 8) passing along the side and bottom surfaces of the housing.

The shape of the housing 111, the arrangement positions of the pins 115 and the base plate 113, and the formation position of the pressing pin groove 140 may be determined so that the creepage distance is appropriately secured in the semiconductor package 100. For example, if the semiconductor package 100 is a 1,000V class product, the creepage distance, which is the shortest distance among the paths L1, L2, and L3, may be secured to be at least 5.00 mm or more. If the semiconductor package 100 is a 1,250V class product, the creepage distance may be secured to be at least 6.30 mm or more. If the semiconductor package 100 is a 1,600V class product, the creepage distance may be secured to be at least 8.00 mm or more.

In order for the shortest distance according to the path L1 in the semiconductor package 100 to be longer than the required creepage distance, as illustrated in FIG. 7, a first distance extension groove 131 may be formed on the upper surface of the housing 111, between the base area 210 of the base plate 113 and the pins 115, in a shape orthogonal to path L1 that connects the base plate 113 and the pins 115 at the shortest distance. The first distance extension groove 131 may be formed to be recessed with a predetermined width and depth, and the size of the recessed first distance extension groove 131 may be determined to correspond to the creepage distance that needs to be secured. In order to secure a sufficient creepage distance, one or more first distance extension grooves 131 may be formed on the top surface of the housing 111 to be orthogonal to the path L1 connecting the base plate 113 and the pins 115 with the shortest distance, and may be arranged in parallel with each other.

In addition, in order for the shortest distance according to the path L2 in the semiconductor package 100 to be longer than the required creepage distance, as illustrated in FIG. 8, a second distance extension groove 133 may be formed in a shape intersecting the path L2 connecting the base plate 113 and the pins 115 with the shortest distance on the bottom surface of the housing 111 between the base area 210 exposed through the pressing pin groove 140 and the pins 115. The second distance extension groove 133 may be formed to be recessed with a predetermined width and depth, and the size of the recessed second distance extension groove 133 may be determined to correspond to the creepage distance that needs to be secured. In order to secure a sufficient creepage distance, one or more second distance extension grooves 131 may be formed on the bottom surface of the housing 111 to intersect the path L2 connecting the base plate 113 and the pins 115 with the shortest distance, and may be arranged in parallel.

Also, in order for the shortest distance according to the path L2 in the semiconductor package 100 to be longer than the required creepage distance, as illustrated in FIG. 8, the pressing pin groove 140 may be located to be closer to the extended area 220 of the base plate 113 than the pins 115. That is, a distance R1 between the pressing pin groove 140 and the pins 115 may be set to be relatively longer than a distance R2 between the pressing pin groove 140 and the extended area 220 of the base plate 113.

FIG. 9 exemplarily illustrates an exterior shape of a semiconductor package according to another embodiment of the present disclosure.

Referring to FIG. 9, a semiconductor package 100 includes a housing 111 that forms an exterior shape sealed with an encapsulant, a base plate 113 that is disposed to be exposed on the top surface of the housing 111, and a plurality of pins 115 that extend outward through one side of the housing 111.

The base plate 113 disposed on the top surface of the housing 111 is consisted of a base area 210 that is located on the top surface of the housing 111 and an extended area 220 extended to be located outside the housing 111. A flat extended portion 121, a first lead portion 123a, and a second lead portion 123b are formed in the extended area 220, which is connected to the base area 210, so as to be spaced apart from each other.

The top surface height of the base area 210 of the base plate 113 and the top surface height of the flat extended portion 121 of the extended area 220 may be the same. Since the base area 210 and the flat extended portion 121 of the base plate 113 have the same top surface height, a heat sink can be in contact with the base area 210 and the flat extended portion 121 together, and heat generated during operation of the semiconductor component can be effectively dissipated through the heat sink.

The base plate 113 may be formed integrally, in which the base area 210 and the extended area 220 are connected as one body. In this case, a recessed groove may be formed at an end of the base area 210 so that an encapsulant is injected to form a contact zone covering an edge area of the base area 210.

Alternatively, the base plate 113 may be formed by fixing the separated base area 210 and extended area 220 so that they are in contact with each other. In this case, in order to form a contact zone at an area where the base area 210 and the extended area 220 are in contact, the base area 210 and the extended area 220, each formed in an L shape, are arranged to be in contact in a lateral direction to form a recessed groove, and the encapsulant is injected into the formed groove.

In the extended area 220 of the base plate 113, the first lead portion 123a and the second lead portion 123b, which are spaced apart in the lateral direction of the flat extended portion 121, have a smaller thickness than the flat extended portion 121 and may be arranged to have a relatively lower top surface height.

Since the first lead portion 123a and the second lead portion 123b are formed to have a relatively small width and thickness, a relatively small force is generated during a forming process for bending the first lead portion 123a and the second lead portion 123b, and the generated small force is dispersed through the contact zone (CZ), thereby preventing a bending phenomenon of the base area 210.

As described above, the semiconductor package 100 according to this embodiment is characterized in that a bending phenomenon of the base area 210 of the base plate 113 is prevented even when a portion of the extended area 220 of the base plate 113 is bent to form the first lead portion 123a and the second lead portion 123b, thereby securing operational reliability of the semiconductor package 100. In addition, it is also characterized in that a creepage distance satisfying a reference value required for a high-withstand voltage semiconductor package is sufficiently secured between the pins 115 and the base plate 113.

Although the present disclosure has been described with reference to the embodiment, it will be understood by those skilled in the art that various modifications and changes can be made to the present disclosure without departing from the spirit and scope of the disclosure as set forth in the following claims.

What is claimed is:

1. A semiconductor package, comprising:
a housing forming an outer shape sealed with an encapsulant;
a base plate fixed to a top surface of the housing so as to be exposed, the base plate including:
a first lead portion; and
a second lead portion, the first lead portion and the second lead portion to be electrically connected to a printed circuit board; and
a plurality of pins extending in a first lateral direction of the housing so as to be exposed, and to be electrically connected to the printed circuit board,
wherein a bottom surface of the housing is to face the printed circuit board to electrically connect the semiconductor package to the printed circuit board,
wherein the base plate comprises:
a base area located on the top surface of the housing; and
an extended area located outside the housing by extending from the base area in a second lateral direction which is a direction opposite to the first lateral direction, the extended area including the first lead portion and the second lead portion,
wherein the base area is exposed upward from the housing and the base plate is fixed to the housing such that an edge area of the base area is continuously covered with the encapsulant, and
wherein, the base area further includes a contact zone which is a partial area of the housing that exists between the base area and the extended area to separate the base area and the extended area.

2. The semiconductor package of claim 1, wherein the extended area further comprises a flat extended portion connected to the base area and extending outward from the housing, and each of the first lead portion and the second lead portion is connected to the base area and extending outward and bent from the housing so that the first lead portion and the second lead portion are at a height corresponding to the bottom surface of the housing,
wherein the first lead portion and the second lead portion are respectively located to be spaced apart from each other on both sides of the flat extended portion so that the flat extended portion is interposed therebetween, and
wherein, in the first lead portion, the flat extended portion, and the second lead portion disposed side by side in a width direction, each of the first lead portion and the second lead portion is formed to have a width smaller than a width of the flat extended portion.

3. The semiconductor package of claim 2, wherein based on the base plate being fixed to the housing such that the base area is exposed upward and the edge area of the base area is continuously surrounded by the housing, T-shaped protrusions connected to the base area are formed at each of both ends of the extended area, and a central area is formed in a shape protruding from the base area so as to be spaced apart between the T-shaped protrusions, and a π-shaped protrusion is formed outward from the central area, and outer ends of the T-shaped protrusions and an outer end of the π-shaped protrusion are connected to each other,
the T-shaped protrusions and the central area are separated from each other by cutting the π-shaped protrusion in a trimming process,
wherein the central area is maintained as the flat extended portion, and each of the T-shaped protrusions is formed into the first lead portion and the second lead portion by a forming process.

4. The semiconductor package of claim 2, wherein the base area is an area to be in contact with a heat sink for heat dissipation, and the flat extended portion, which is located lower than a top surface of the base area, is to dissipate heat into air.

5. The semiconductor package of claim 4, wherein a first distance extension groove is formed in the top surface of the housing between the base area and the plurality of pins, and the first distance extension groove is in a shape orthogonal to a first shortest path so that a distance of the first shortest path between the base area and the plurality of pins exposed in the top surface of the housing is 6.3 mm or more.

6. The semiconductor package of claim 4, wherein a side surface of the housing has a pressing pin groove formed thereon to expose a bottom surface of the base area, and the pressing pin groove is formed at a position closer to the extended area than a position of the plurality of pins.

7. The semiconductor package of claim 6, wherein a second distance extension groove is formed in the bottom surface of the housing between the pressing pin groove and the plurality of pins, and the second distance extension groove is in a shape intersecting a second shortest path so that a distance of the second shortest path between the base area exposed through the pressing pin groove and the plurality of pins is 6.3 mm or more.

8. The semiconductor package of claim 2, wherein the base area and the flat extended portion separated by the contact zone have a same height as a height of the top surface of the housing so that the base area and the flat extended portion are to be in contact with a heat sink for heat dissipation together.

9. The semiconductor package of claim 8, wherein, a first distance extension groove is formed in the top surface of the housing between the base area and the plurality of pins, and the first distance extension groove is in a shape orthogonal to a first shortest path so that a distance of the first shortest path between the base area and the plurality of pins exposed in the top surface of the housing is 6.3 mm or more.

10. The semiconductor package of claim 8, wherein a side surface of the housing has a pressing pin groove form thereon to expose a bottom surface of the base area, and the pressing pin groove is formed at a position closer to the extended area than a position of the plurality of pins.

11. The semiconductor package of claim 10, wherein, a second distance extension groove is formed in a bottom surface of the housing between the pressing pin groove and the plurality of pins, and the second distance extension groove is in a shape intersecting a second shortest path so that a distance of the second shortest path between the base area exposed through the pressing pin groove and the plurality of pins is 6.3 mm or more.

12. The semiconductor package of claim 2, wherein the base area is to be in contact with a heat sink for heat dissipation, one or more semiconductor components are to be mounted on a surface opposite to the base area in contact with the heat sink, and the one or more semiconductor components are to be sealed with the encapsulant and located inside the housing.
